(19) United States
(12) Patent Application Publication
(10) Pub. No.: US 2024/0244939 A1
(43) Pub. Date: Jul. 18, 2024

(54) DISPLAY APPARATUS, DISPLAY PANEL AND MANUFACTURING METHOD THEREFOR

(71) Applicants: Chengdu BOE Optoelectronics Technology Co., Ltd., Sichuan (CN); BOE Technology Group Co., Ltd., Beijing (CN)

(72) Inventors: Quan SHI, Beijing (CN); Bo SHI, Beijing (CN); Guanghua XU, Beijing (CN); Zeyu LI, Beijing (CN); Chi YU, Beijing (CN); Haijun QIU, Beijing (CN); Ming HU, Beijing (CN); Weiyun HUANG, Beijing (CN); Xiangdan DONG, Beijing (CN); Hui GUAN, Beijing (CN)

(21) Appl. No.: 18/563,460

(22) PCT Filed: Feb. 28, 2022
(86) PCT No.: PCT/CN2022/078191

§ 371 Date: Nov. 22, 2023

(51) Int. Cl. H10K 59/80; H10K 59/12; H10K 59/122; H10K 59/40

(52) U.S. Cl. CPC H10K 59/879; H10K 59/1201; H10K 59/122; H10K 59/40

(57) ABSTRACT

A display panel includes a driving backplane, a plurality of light-emitting devices spaced apart at a side of the driving backplane a pixel definition layer located at a same side of the driving backplane as the light-emitting device and provided with a plurality of openings and a lens layer located at a side of the light-emitting device away from the driving backplane. The lens layer includes a separating lens and an intermediate lens, the separating lens is provided with a light-transmitting hole, and the intermediate lens is located within a range surrounded by the light-transmitting hole and is spaced apart from a sidewall of the light-transmitting hole. The display panel further includes a dielectric layer covering the lens layer and filling the light-transmitting hole, and a cover plate located at a side of the dielectric layer away from the driving backplane.

### TECHNICAL FIELD

The present disclosure relates to the field of display technologies, and specifically to a display apparatus, a display panel, and a manufacturing method of a display panel.

### BACKGROUND

A display panel is an indispensable component of an electronic device such as a cell phone and a computer. The display panel includes a liquid crystal display panel, an organic electroluminescent display panel, etc. Currently, people have increasingly high requirements for display effects, but the brightness of the existing display panels still needs to be improved, and abnormal display phenomena such as color deviation are prone to occur.

It should be illustrated that the information disclosed in the above-described background section is only used to enhance the understanding of the background of the present disclosure, and thus may include information that does not constitute prior art known to those ordinary skilled in the art.

### SUMMARY

The present disclosure provides a display apparatus, a display panel, and a manufacturing method of a display panel.

According to an aspect of the present disclosure, a display panel is provided. The display panel includes:
a driving backplane;
a plurality of light-emitting devices, spaced apart at a side of the driving backplane;
a pixel definition layer, located at a same side of the driving backplane as the light-emitting device, and provided with a plurality of openings, where the openings define ranges of the light-emitting devices in one-to-one correspondence;
a lens layer, located at a side of the light-emitting device away from the driving backplane, where the lens layer includes a separating lens and an intermediate lens, the separating lens is provided with a light-transmitting hole, the intermediate lens is located within a range surrounded by the light-transmitting hole and is spaced apart from a sidewall of the light-transmitting hole; in a direction perpendicular to the driving backplane, one of the openings is located opposite to the light-transmitting hole; sizes of the light-transmitting hole and the opening expand in a direction away from the driving backplane, and an outer peripheral surface of the intermediate lens contracts in the direction away from the driving backplane;
a dielectric layer, covering the lens layer and filling the light-transmitting hole, where the dielectric layer has a larger refractive index than the lens layer; and
a cover plate, located at a side of the dielectric layer away from the driving backplane.

In an exemplary embodiment of the present disclosure, the light-emitting device includes a first electrode, a light-emitting layer, and a second electrode sequentially stacked in the direction away from the driving backplane;
first electrodes of the light-emitting devices are spaced apart, and are exposed by the openings in one-to-one correspondence; the light-emitting devices share the same second electrode; the second electrode covers on a side of the pixel definition layer away from the driving backplane and recesses into the opening; and the lens layer is located at a side of the second electrode away from the driving backplane; and
an orthogonal projection of the separating lens on the driving backplane is located within a range covered by the pixel definition layer, and the intermediate lens is located in the opening.

In an exemplary embodiment of the present disclosure, the display panel further includes:
an encapsulation layer, covering the light-emitting devices; and
a touch layer, located on a surface of the encapsulation layer away from the driving backplane; where the lens layer covers the touch layer; and the transparent cover plate is located at a side of the touch layer away from the driving backplane.

In an exemplary embodiment of the present disclosure, in one of the openings and the intermediate lens in the light-transmitting hole corresponding to the one of the openings, an orthogonal projection of the intermediate lens on the driving backplane covers a center of an orthogonal projection of the opening on the driving backplane.

In an exemplary embodiment of the present disclosure, the light-transmitting hole is surrounded by a plurality of sidewalls; and the outer peripheral surface of the intermediate lens includes at least one lens side surface parallel to an orthogonal projection, on the driving backplane, of at least one of the sidewalls of the light-transmitting hole where the intermediate lens is located.

In an exemplary embodiment of the present disclosure, a width of the light-transmitting hole in a row direction is less than a length of the light-transmitting hole in a column direction; and a width of the intermediate lens in the row direction is less than a length of the intermediate lens in the column direction.

In an exemplary embodiment of the present disclosure, the intermediate lens is a strip-shape structure extending along the column direction;
in the row direction, a ratio of the width of the intermediate lens to the width of the light-transmitting hole where the intermediate lens is located is not less than 10% and not more than 50%; and
in the column direction, a ratio of the length of the intermediate lens to the length of the light-transmitting hole where the intermediate lens is located is not less than 30% and not more than 80%.

In an exemplary embodiment of the present disclosure, two lens side surfaces of the intermediate lens both have a plurality of recessed portions spaced apart;
in the row direction, a ratio of a depth of the recessed portion to the width of the intermediate lens is not less than 20% and not more than 25%; and
in the column direction, a ratio of a distance, between one end of the intermediate lens and a lowest point of the recessed portion closest to the one end, to the length of the intermediate lens is not less than 10% and not more than 50%.

In an exemplary embodiment of the present disclosure, the outer peripheral surface of the intermediate lens is surrounded and smoothly connected by a plurality of curved lens side surfaces.

In an exemplary embodiment of the present disclosure, the intermediate lens includes a plurality of extension portions radially distributed, and at least one of the extension portions is parallel to an orthogonal projection, on the driving backplane, of a sidewall of the light-transmitting hole where the intermediate lens is located.

In an exemplary embodiment of the present disclosure, the outer peripheral surface of the intermediate lens has a same shape on the driving backplane as the light-transmitting hole where the intermediate lens is located.

In an exemplary embodiment of the present disclosure, the light-transmitting hole is surrounded by two planar sidewalls and one curved sidewall; and the outer peripheral surface of the intermediate lens is surrounded by two planar side surfaces and one curved side surface; and
the two planar side surfaces are parallel to orthographic projections, on the driving backplane, of the two planar sidewalls respectively.

In an exemplary embodiment of the present disclosure, the light-transmitting hole is surrounded by two planar sidewalls and one curved sidewall; and the intermediate lens is a strip-shape structure, and is located between the curved sidewall and a center of the light-transmitting hole where the intermediate lens is located.

In an exemplary embodiment of the present disclosure, the intermediate lens includes a first segment and a second segment connected at a specified angle, and the first segment and the second segment are symmetrically arranged about a central axis passing through, in a column direction, the center of the light-transmitting hole.

In an exemplary embodiment of the present disclosure, the intermediate lens is a curved-strip-shape structure extending along a direction parallel to the curved sidewall of the light-transmitting hole where the intermediate lens is located.

In an exemplary embodiment of the present disclosure, the intermediate lens is of an annular shape and surrounds outside a center of the light-transmitting hole where the intermediate lens is located.

In an exemplary embodiment of the present disclosure, the intermediate lens includes a plurality of lens units spaced apart around the center of the light-transmitting hole where the intermediate lens is located.

In an exemplary embodiment of the present disclosure, the curved sidewall has a same slope as the planar sidewall.

According to an aspect of the present disclosure, a manufacturing method of a display panel is provided. The manufacturing method includes:
forming a driving backplane;
forming a pixel definition layer and a plurality of light-emitting devices at a side of the driving backplane, where the plurality of light-emitting devices are spaced apart at the side of the driving backplane, and the pixel definition layer is provided with a plurality of openings defining ranges of the light-emitting devices in one-to-one correspondence;
forming a lens layer at a side of the light-emitting device away from the driving backplane, where the lens layer includes a separating lens and an intermediate lens, the separating lens is provided with a light-transmitting hole, the intermediate lens is located within a range surrounded by the light-transmitting hole and is spaced apart from a sidewall of the light-transmitting hole; in a direction perpendicular to the driving backplane, one of the openings is located opposite to the light-transmitting hole and has a same shape as the light-transmitting hole; sidewalls of the light-transmitting hole and the opening expand in a direction away from the driving backplane, and an outer peripheral surface of the intermediate lens contracts in the direction away from the driving backplane;
forming a dielectric layer covering the lens layer and filling the light-transmitting hole, where the dielectric layer has a larger refractive index than the lens layer; and
forming a transparent cover plate at a side of the dielectric layer away from the driving backplane.

According to an aspect of the present disclosure, a display apparatus is provided. The display apparatus includes the display panel according to any of the above.

It should be understood that the general description above and the detailed description in the following text are only illustrative and explanatory, and do not limit the present disclosure.

### BRIEF DESCRIPTION OF THE DRAWINGS

The accompanying drawings herein are incorporated into and form a part of the specification, illustrate embodiments consistent with the present disclosure, and are used in conjunction with the specification to explain the principles of the present disclosure. It is apparent that the accompanying drawings in the following description are only some of the embodiments of the present disclosure. For those ordinary skilled in the art, other accompanying drawings may be obtained based on these drawings without creative labor.

FIG. 1 is a cross-sectional view of a display panel in an embodiment of the present disclosure.

FIG. 2 is a cross-sectional view of a display panel in another embodiment of the present disclosure.

FIG. 3 is a cross-sectional view of a display panel in yet another embodiment of the present disclosure.

FIG. 4 is a schematic diagram of a light-transmitting hole and an opening in an embodiment of a display panel of the present disclosure.

FIG. 5 is a schematic diagram of an opening in an embodiment of a display panel of the present disclosure.

FIGS. 6-10 are schematic diagrams of an intermediate lens covering a center of a light-emitting device of a display panel in multiple embodiments of the present disclosure.

FIGS. 11-20 are schematic diagrams of an intermediate lens not covering a center of a light-emitting device of a display panel in multiple embodiments of the present disclosure.

FIG. 21 is a schematic diagram of a distribution manner of light-emitting devices in an embodiment of a display panel of the present disclosure.

FIG. 22 is a schematic diagram of step S130 in an embodiment of a manufacturing method of a display panel of the present disclosure.

### DETAILED DESCRIPTION

Example embodiments are now described more comprehensively with reference to the accompanying drawings. However, the exemplary embodiments are capable of being implemented in a variety of forms and should not be construed as being limited to the embodiments set forth herein; rather, the provision of these embodiments allows the present disclosure to be comprehensive and complete and conveys the idea of the exemplary embodiments comprehensively to those skilled in the art. The same reference numerals in the drawings indicate the same or similar structures, therefore their detailed descriptions will be omitted. In addition, the accompanying drawings are only illustrative illustrations of the present disclosure and are not necessarily drawn to scale.

The terms “a”, “an”, “this”, “the”, and “at least one” are used for indicating the presence of one or more elements/components/etc.; the terms “include” and “has” are used for indicating open inclusion and meaning that there may be additional elements/components/etc. in addition to the listed elements/components/etc. The terms “first”, “second”, “third”, etc., are used only as markers and are not intended to be quantitative limitations of the objects to which they refer.

The row direction X and the column direction Y herein are only two mutually perpendicular directions. In the accompanying drawings of the present disclosure, the row direction X may be horizontal and the column direction Y may be vertical, but not limited to this. If the display panel is rotated, the actual orientation of the row direction X and the column direction Y may be changed. The X direction in the accompanying drawings exemplarily illustrates the row direction, and the Y direction in the accompanying drawings exemplarily illustrates the column direction.

In related arts, the display panel may include a driving backplane and a plurality of light-emitting devices located at a side of the driving backplane. The light-emitting devices may be organic light-emitting diodes (OLEDs). Image display may be achieved through controlling the light-emitting device to emit light independently by the driving backplane. At the same time, the display panel further includes a transparent cover plate, and the transparent cover plate may cover on a side of the light-emitting device away from the driving backplane for protection. The light emitted by the light-emitting device emits from the transparent cover plate into the air outside the display panel. The material of the transparent cover plate may be glass, etc. The refractive index of the material of the transparent cover plate is larger than that of the air. Therefore, when the light enters the air from the transparent cover plate, the light with an incident angle that reaches a total reflection critical angle may undergo total reflection at an interface between the transparent cover plate and the air, and cannot be emitted from the transparent cover plate, resulting in low light output efficiency of the display panel. During this process, the larger the incident angle of the light irradiated on the transparent cover plate, the more likely it is to undergo the total reflection.

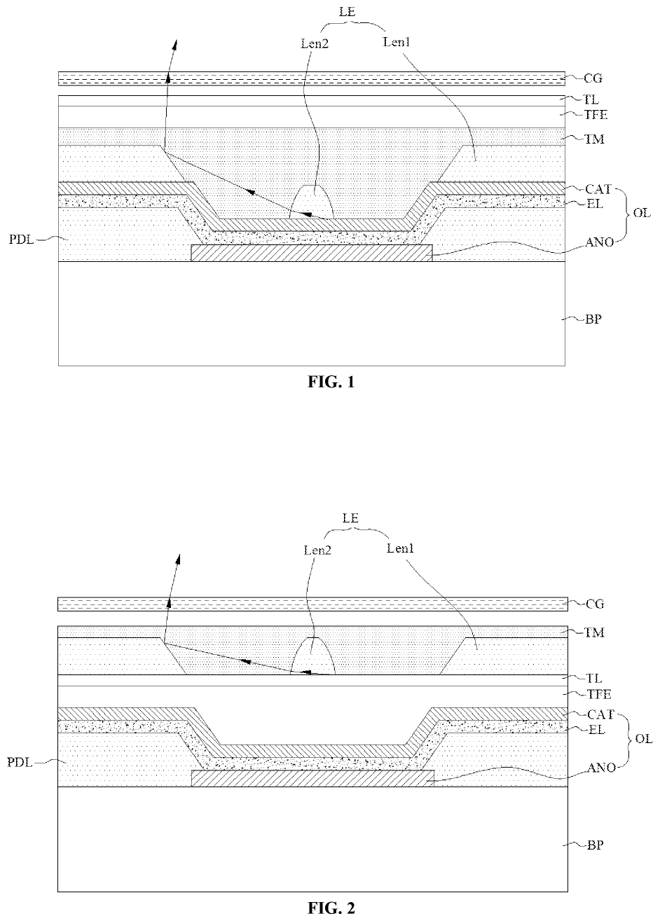

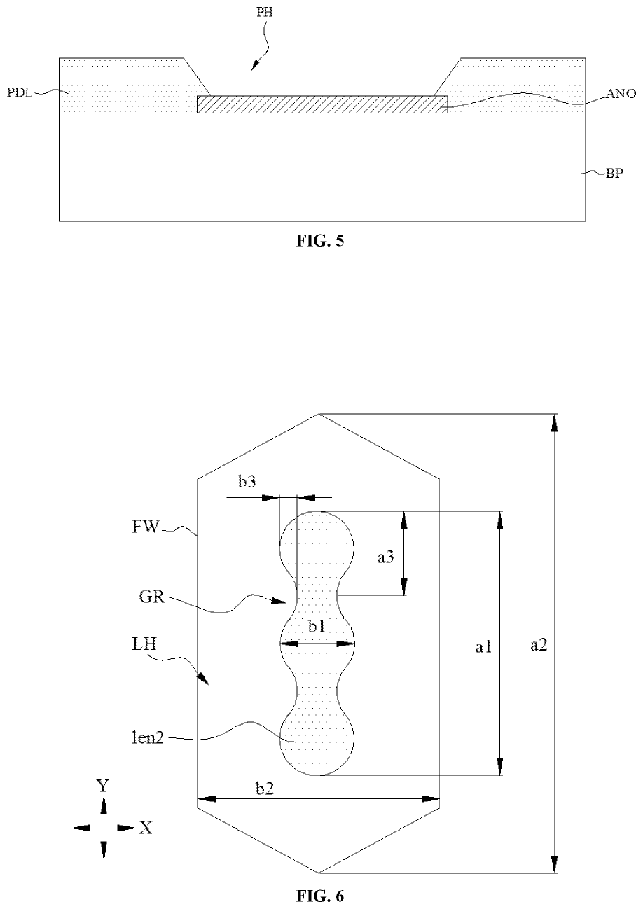

An embodiment of the present disclosure provides a display panel. As shown in FIGS. 1 to 6, 11, and 17, the display panel may include a driving backplane BP, light-emitting devices OL, a pixel definition layer PDL, a lens layer LE, a dielectric layer TM, and a transparent cover plate CG.

The number of the light-emitting devices OL is multiple, and the light-emitting devices are spaced apart at a side of the driving backplane BP. The pixel definition layer PDL and the light-emitting device OL are located at the same side of the driving backplane BP. The pixel definition layer PDL is provided with a plurality of openings PH. The openings PH define ranges of the light-emitting devices OL in one-to-one correspondence.

The lens layer LE is located at a side of the light-emitting device OL away from the driving backplane BP. The lens layer LE includes a separating lens Len1 and an intermediate lens Len2. The separating lens Len1 is provided with a light-transmitting hole LH. The intermediate lens Len2 is located within a range surrounded by the light-transmitting hole LH, and is spaced apart from a sidewall of the light-transmitting hole LH. In a direction perpendicular to the driving backplane BP, one opening PH is located opposite to one light-transmitting hole LH and has the same shape as the light-transmitting hole LH. The light-transmitting hole LH and the opening PH expand in a direction away from the driving backplane BP. An outer peripheral surface of the intermediate lens Len2 contracts in the direction away from the driving backplane BP.

The dielectric layer TM covers the lens layer LE and fills the light-transmitting hole LH. The dielectric layer TM has a larger refractive index than the lens layer LE. The transparent cover plate CG is located at a side of the dielectric layer TM away from the driving backplane BP.

In the display panel of the embodiments of the present disclosure, light emitted by the light-emitting device OL propagates in the direction away from the driving backplane BP. Due to the refractive index of the lens dielectric layer being larger than the refractive index of the lens layer LE, a portion of the light emitted by the light-emitting device OL may undergo total reflection at the sidewall of the light-transmitting hole LH, reducing the degree of light divergence and causing light convergence. Compared to light without this total reflection process, the incident angle of the light when propagating to the transparent cover plate CG after the total reflection is smaller, making it less prone to total reflection, which is beneficial for improving the light output efficiency. At the same time, due to the presence of the intermediate lens Len2 inside the light-transmitting hole LH, the intermediate lens Len2 may refract a portion of the light emitted by the light-emitting device OL, this can also converge the light and increase the incident angle of the light when reaching the sidewall of the light-transmitting hole LH after passing through the intermediate lens Len2, making the light easier to undergo the total reflection, thereby reducing the incident angle of the light when it propagates to the transparent cover plate CG and further improving the light output efficiency. FIGS. 1 to 3 show the effect of the intermediate lens Len2 and the separating lens Len1 on the light path. It can be seen that, due to the presence of the intermediate lens Len2 and the separating lens Len1, light can be emitted out at the interface between the transparent cover plate and the air without undergoing total reflection.

The following provides a detailed illustration of the display panel in the present disclosure.

Firstly, an exemplary illustration of the basic architecture of the display panel in the present disclosure is provided.

As shown in FIGS. 1 to 5, the display panel may include a driving backplane BP, and a pixel definition layer PDL and a plurality of light-emitting devices OL located at the same side of the driving backplane BP. The driving backplane BP is provided with a driving circuit that may drive the light-emitting device OL to emit light to display images.

The driving backplane BP may include a substrate and a circuit layer located at a side of the substrate. The substrate may be a tabulate structure, and its material may be hard materials such as glass or soft materials such as polyimide. At the same time, the substrate may be a single-layer or multi-layer structure. Taking the multi-layer structure as an example, the substrate may include multi-layer base substrates, and respective ones of the multi-layer base substrates are stacked in the multi-layer structure.

The circuit layer may be located at a side of the substrate. For example, for each one of the base substrates, the circuit layer may be located at a side of a barrier layer, of the substrate, away from an insulation support layer. Before forming the circuit layer, a buffer layer may be formed on the substrate, and the circuit layer may be set on a surface of the buffer layer away from the substrate. The material of the buffer layer may include insulation materials such as silicon nitride and silicon oxide.

The circuit layer may include the driving circuit. The driving circuit may drive the light-emitting device OL to emit light. For example, the display panel may be at least divided into a display area and a peripheral area located outside the display area. Correspondingly, an area of the circuit layer corresponding to the display area is a pixel area, and an area of the circuit layer corresponding to the peripheral area is an edge area, that is, the edge area is located outside the pixel area. The driving circuit may include a pixel circuit located in the pixel area and a peripheral circuit located in the edge area. The pixel circuit may be pixel circuits such as 7T1C, 7T2C, 6T1C, or 6T2C, as long as the pixel circuit can drive the light-emitting device OL to emit light, and the structure of the pixel circuit is not specifically limited here. The number of pixel circuits is the same as the number of the light-emitting devices OL, and the pixel circuits are connected to the light-emitting devices OL in one-to-one correspondence, in order to control each of the light-emitting devices OL to emit light separately. nTmC indicates that one pixel circuit includes n transistors (represented by the letter “T”) and m capacitors (represented by the letter “C”). Of course, the same pixel circuit may also be connected to multiple light-emitting devices OL, and drive multiple light-emitting devices OL to emit light at the same time, without special limitations here.

The peripheral circuit may be located in the peripheral area. The peripheral circuit is connected to the pixel circuit for inputting a driving signal to the pixel circuit, in order to control the light-emitting device OL to emit light. The peripheral circuit may include a gate driving circuit and a light-emitting control circuit. Of course, the peripheral circuit may include other circuits. The specific structure of the peripheral circuit is not specifically limited here.

The circuit layer described above may include a plurality of thin film transistors and capacitors. The thin film transistors may be top gate or bottom gate type thin film transistors. Each of the thin film transistors may include an active layer and a gate. The active layers of the thin film transistors are provided in the same layer and are provided in the same semiconductor layer, and the gates of the thin film transistors are provided in the same layer and are provided in the same gate layer, in order to simplify the process.

Taking the top gate type thin film transistors as an example, the circuit layer may include a semiconductor layer, a first gate insulation layer, a first gate layer, a second gate insulation layer, a second gate layer, an interlayer dielectric layer, a first source drain layer, a passivation layer, a first planarization layer, a second source drain layer, and a second planarization layer. The specific patterns of the film layers depend on the specific composition of the driving circuit, and there are no special limitations here.

As shown in FIGS. 1 to 5, the pixel definition layer PDL and the light-emitting devices OL may be located at the same side of the driving backplane BP. For example, the pixel definition layer PDL and the light-emitting devices OL may be located on a surface of the second planarization layer away from the substrate. Orthogonal projections of the light-emitting devices OL on the circuit layer may be located in the pixel area, i.e., in the display area of the display panel, while the edge area may be left without setting the light-emitting device OL. Each light-emitting device OL may include a first electrode ANO, a second electrode CAT, and a light-emitting layer EL located between the first electrode ANO and the second electrode CAT. By applying an electrical signal to the first electrode ANO and the second electrode CAT, the light-emitting layer EL may be excited to emit light. The light-emitting device OL may be an organic light-emitting diode (OLED).

As shown in FIGS. 1 to 5, first electrodes ANO of the light-emitting devices OL are spaced apart. The pixel definition layer PDL is provided with openings PH that expose the first electrodes ANO, that is, one opening PH exposes one first electrode ANO. The pixel definition layer PDL may be used for defining the light-emitting devices OL, and a range corresponding to an opening PH is a range of one light-emitting device OL. The shape of the opening PH may be a rectangle, pentagon, hexagon, or other polygon, as well as an ellipse, fan, or other shape. There is no special limitation on the shape of the opening PH here.

The light-emitting layer EL is at least partially located in the opening PH and is stacked with the first electrode ANO. The light-emitting layer EL may include a hole injection layer, a hole transport layer, a light-emitting material layer, an electron transport layer, and an electron injection layer that are sequentially stacked in the direction away from the driving backplane BP. Of course, other structures may also be used, as long as the light-emitting layer EL can emit light in conjunction with the first electrode ANO and the second electrode CAT. For example, the light-emitting layer EL may include a plurality of light-emitting units spaced apart in the openings PH in one-to-one correspondence. Each of the light-emitting units may emit light independently, and luminescent colors of the light-emitting units may be different, thus directly achieving color display. Alternatively, the light-emitting layer EL may simultaneously cover the pixel definition layer PDL and the first electrodes ANO, meaning that the light-emitting devices OL may share the same light-emitting layer EL. At this time, the luminescent colors of the light-emitting devices OL are the same. To achieve color display, a color film layer may be set at a side of the light-emitting device OL away from the driving backplane BP. The color film layer includes a plurality of light-filtering areas. Each of the light-filtering areas corresponds to one light-emitting device OL, and colors of different light-filtering areas may be different. Each of the light-filtering areas may only transmit one type of monochromatic light, thus achieving color display through the color film layer.

The second electrode CAT may cover the light-emitting layer EL, and the second electrode CAT may be a continuous whole layer structure, allowing the light-emitting devices OL to share the same second electrode CAT. The second electrode CAT may recess into the opening PH at a position of the second electrode CAT corresponding to the opening PH. At the same time, the second electrode CAT may be the cathode of the light-emitting device OL, and the second electrode CAT may adopt a light-transmitting structure, allowing the light-emitting device OL to emit light in the direction away from the driving backplane BP. For example, the material of the second electrode CAT may be metal magnesium, silver, or the alloy thereof, etc., which can transmit light while conducting at a certain thickness. Meanwhile, the first electrode ANO may be an opaque structure, making the light-emitting device OL a top emitting structure.

The second electrode CAT may extend into the edge area and be connected to a common power signal line to receive a common power signal. The common power signal line may be provided in the same layer as the first electrode ANO, so the second electrode CAT may be connected, in the edge area, to the common power signal line by passing through a via of the pixel definition layer PDL. When displaying images, a pixel power signal may be applied to the first electrode ANO through pixel circuit control. The pixel circuit may receive the pixel power signal through the pixel power line located in the second source drain layer, and apply the common power signal to the second electrode CAT through the common power signal line, thereby stimulating the light-emitting layer EL to emit light. The specific principle of the organic electroluminescence is not detailed here.

The following is an exemplary illustration of the arrangement manner of the light-emitting device OL.

The display panel may include a plurality of light-emitting units. Each of the light-emitting units may include a plurality of subunits. One of the subunits may include one light-emitting device OL. When displaying images, adjacent light-emitting units may share at least one subunit. Of course, adjacent light-emitting units may also not share the subunit. The luminescent colors of the subunits of the same light-emitting unit may be different. For example, the number of the subunits of one light-emitting unit is three, and the luminescent colors are red, green, and blue, respectively. In the same light-emitting unit, an area of the subunit emitting blue light may be larger than that of the subunit emitting red light, and an area of the subunit emitting red light may be larger than that of the subunit emitting green light. The area of a subunit is the area of an orthogonal projection, on the driving backplane BP, of the opening PH where the light-emitting device OL of the subunit is located.

For a light-emitting device OL that needs to be matched with a color film to achieve color display, one light-emitting device OL and its corresponding light-filtering area may serve as a subunit. For a light-emitting device OL that does not need to be matched with the color film to achieve color display, one light-emitting device OL may serve as a subunit.

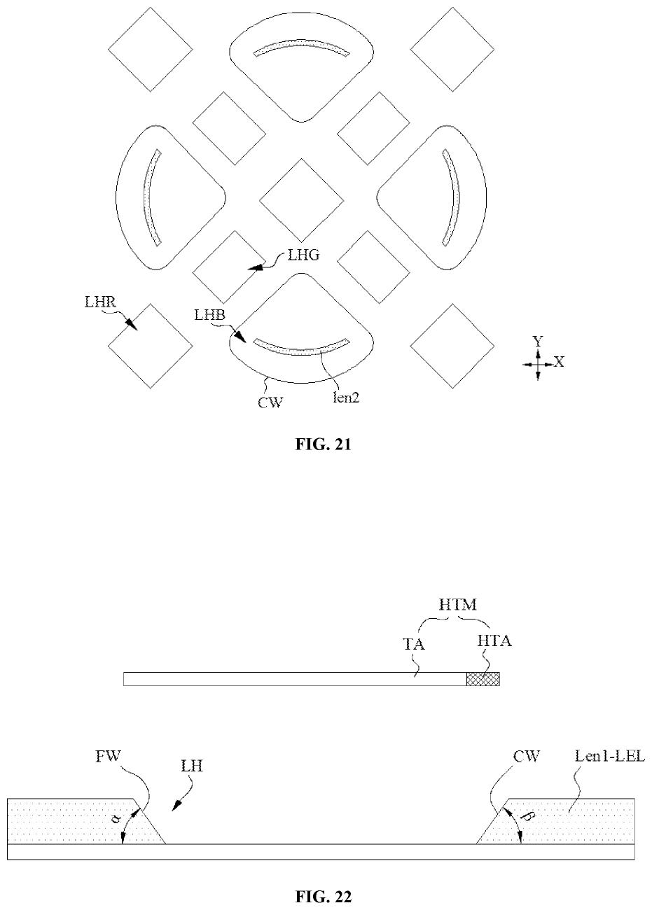

The shape of the subunit is the shape of its corresponding opening PH of the pixel defining layer PDL. For example, the same light-emitting unit may include four subunits, i.e., a first subunit that emits blue light, a second subunit that emits red light, and two third subunits that emit green light. An area of the first subunit is larger than that of the second subunit, and an area of the second subunit is larger than that of the third subunit. In one light-emitting unit, two third subunits may be located between the first subunit and the second subunit. Each subunit may be represented by a corresponding light-transmitting hole. As shown in FIG. 21, a light-transmitting hole LHB corresponds to the first subunit, a light-transmitting hole LHR corresponds to the second subunit, a light-transmitting hole LHG corresponds to the third subunit, the light-transmitting hole LHB has a larger range than the light-transmitting hole LHR, and the light-transmitting hole LHR has a larger range than the light-transmitting hole LHG.

In addition, as shown in FIGS. 1-3, the display panel may further include an encapsulation layer TFE, and the encapsulation layer TFE may cover the light-emitting devices OL for protecting the light-emitting layer EL and blocking water and oxygen from the outside from eroding the light-emitting device OL. For example, the encapsulation layer TFE may be encapsulated by means of a thin film encapsulation, and the encapsulation layer TFE may include a first inorganic layer, an organic layer, and a second inorganic layer. The first inorganic layer covers a side of the second electrode CAT away from the driving backplane BP. The organic layer may be provided on a surface of the first inorganic layer away from the driving backplane BP. A boundary of the organic layer is defined to an inner side of a boundary of the first inorganic layer. A boundary of an orthographic projection of the organic layer on the driving backplane BP may be located in the peripheral area, ensuring that the organic layer may cover the light-emitting devices OL. The second inorganic layer may cover the organic layer and the first inorganic layer not covered by the organic layer. Water and oxygen intrusion may be blocked by the second inorganic layer, and planarization may be achieved through the organic layer having flexibility.

As shown in FIGS. 1-3, the display panel of the present disclosure may further include a touch layer TL. The touch layer TL may be located at a side of the encapsulation layer TFE away from the driving backplane BP and is used for sensing a touch operation. Taking the touch layer TL adopting a mutual capacitive touch control structure as an example, the touch layer TL may include a plurality of first touch electrodes and a plurality of second touch electrodes. The first touch electrodes are spaced apart along the row direction X. One first touch electrode may include a plurality of first electrode blocks spaced apart along the column direction Y and an adapter bridge connecting two adjacent first electrode blocks. The second touch electrodes are spaced apart along the column direction Y One second touch electrode includes a plurality of second electrode blocks connected in series along the row direction X. One adapter bridge is intersected with and is insulated from one second touch electrode. Specifically, the touch layer TL may include a buffer layer, an adapter layer, an isolation layer, and an electrode layer.

The buffer layer may be located on a surface of the encapsulation layer TFE away from the driving backplane BP. The material of the buffer layer may be an insulation material such as silicon nitride or silicon oxide, and is not specifically limited herein. The adapter layer may be provided on a surface of the buffer layer away from the driving backplane BP, and includes a plurality of adapter bridges distributed in an array as described above. The material of the adapter layer may be metal or other conductive material. The isolation layer may cover the adapter layer, and the material of the isolation layer may be an insulation material such as silicon nitride or silicon oxide, and is not specifically limited herein. The electrode layer is located on a surface of the isolation layer away from the driving backplane BP, and includes the first electrode block and the second electrode block as described above.

In addition, a planarization layer may be covered on the touch layer TL for achieving planarization so as to form a film layer on the touch layer TL. The material of the planarization layer may be a resin or other transparent insulation material, which is not specifically limited herein. For example, the planarization layer may cover the electrode layer.

In addition, in some embodiments of the present disclosure, the display panel may further include a polarizing layer. The polarizing layer may be located at a side of the touch layer TL away from the driving backplane BP. The polarizing layer is a circular polarizer that reduces the reflection effect on external light, the specific principles of which are not described in detail herein.

As shown in FIGS. 1-3, the transparent cover plate CG of the present disclosure may be located at the side of the light-emitting device OL away from the driving backplane BP. For example, the transparent cover plate CG covers the polarizing layer and may achieve planarization. The transparent cover plate CG is used for protecting the film layer underneath, and the material of the transparent cover plate CG may be a transparent material such as glass or acrylic, and is not specifically limited herein.

Since the refractive index of the transparent cover plate CG is larger than the refractive index of the air, a portion of the light emitted by any one of the light-emitting devices OL has an incident angle at the interface between the transparent cover plate CG and the air that is larger than the total reflection critical angle, and thus total reflection occurs, and light cannot be emitted out from the transparent cover plate CG to the air. The inventor has found that the light that undergoes total reflection at the transparent cover plate CG is mainly the light located at the edge of the light-emitting range of the light-emitting device OL, and this light forms a larger angle with the light emitted from the direction perpendicular to the direction of the driving backplane BP, i.e., is more dispersed, and is easy to reach the total reflection critical angle at the transparent cover plate CG. In some embodiments, the area of the light-emitting device OL that emits blue light is larger than the area of the light-emitting device OL that emits red light and green light, and more light reaches the total reflection critical angle, making the light output efficiency of the blue light lower than that of the red light and the green light, which is prone to abnormal display phenomena such as color deviation, and is not conducive to improving the overall brightness of the display panel.

Based on this, as shown in FIGS. 1-3, the inventor, by means of the lens layer LE and the dielectric layer TM having a larger refractive index than the lens layer LE, at least can make the light located at the edge of the light-emitting range of the light-emitting device OL converge to the optical axis, i.e., narrow the angle between this light and the direction perpendicular to the driving backplane BP, thus reducing the incident angle of this light at the interface between the transparent cover plate CG and the air, avoiding to reach the total reflection critical angle, and making this light be emitted out normally without undergoing total reflection, thereby improving the light output efficiency.

The lens layer LE and the dielectric layer TM of the present disclosure are described in detail below.

As shown in FIGS. 1-3 and FIGS. 6 and 11, the lens layer LE is located at a side of the light-emitting device OL away from the driving backplane BP. The lens layer LE includes a separating lens Len1 and an intermediate lens Len2. The separating lens Len1 may be provided with a light-transmitting hole LH that passes through the lens layer LE. The light-transmitting hole LH may be surrounded by a plurality of sidewalls, and of course may be surrounded by the same circular, elliptical, and other closed curved surfaces. The intermediate lens Len2 may be located within a range surrounded by the light-transmitting hole LH and may be spaced apart from the sidewall of the light-transmitting hole LH, i.e., an orthogonal projection of one light-transmitting hole LH on the driving backplane BP surrounds outside an orthogonal projection of one intermediate lens Len2 on the driving backplane BP, and there is a gap between the two.

As shown in FIGS. 1-3, in a direction perpendicular to the driving backplane BP, one opening PH of the pixel definition layer PDL is located opposite to one light-transmitting hole LH and has the same shape as the light-transmitting hole LH. An orthogonal projection of one opening PH on the driving backplane BP and an orthogonal projection of one light-transmitting hole LH on the driving backplane BP at least partially overlap, and the orthogonal projections are of the same shape. For example, the orthogonal projection of one opening PH on the driving backplane BP is located within the orthogonal projection of one light-transmitting hole LH on the driving backplane BP. That is, one light-emitting device OL corresponds to one light-transmitting hole LH. Of course, one light-transmitting hole LH may also correspond to a plurality of light-emitting devices OL at the same time. The sidewall of the light-transmitting hole LH and the sidewall of the opening PH expand in the direction away from the driving backplane BP, i.e., the sidewall of the light-transmitting hole LH and the sidewall of the opening PH are sloped surfaces expanded in the direction away from the driving backplane BP. An outer peripheral surface of the intermediate lens Len2 may contract in the direction away from the driving backplane BP.

As shown in FIGS. 1-3, the dielectric layer TM may cover the lens layer LE and fill the light-transmitting hole LH. A surface of the dielectric layer TM away from the driving backplane BP may be planar, i.e., the dielectric layer TM may play a role of planarization. A portion of the light emitted by the light-emitting device OL may be irradiated through the dielectric layer TM to the sidewall of the light-transmitting hole LH, i.e., to the interface where the separating lens Len1 is in contact with the dielectric layer TM. Since the refractive index of the dielectric layer TM is larger than the refractive index of the lens layer LE, when the incident angle of the light reaches the total reflection critical angle, the light may undergo total reflection without passing through the separating lens, so as to at least cause a portion of the light to be propagated in a direction towards the direction perpendicular to the driving backplane BP, thereby narrowing the incident angle at the transparent cover plate CG, avoiding total reflection at the interface between the transparent cover plate CG and the air, which is beneficial for improving the light output efficiency.

At the same time, as shown in FIGS. 1-3, since the intermediate lens Len2 in the light-transmitting hole LH may refract a portion of the light of the light-emitting device OL, causing that the light is further converged towards the direction perpendicular to the driving backplane BP, further avoiding total reflection at the interface between the transparent cover plate CG and the air, which is conducive to improving the light output efficiency.

The material of the lens layer LE may be a resin or other transparent insulation material, and the lens layer LE may be formed in the same material as the pixel definition layer PDL so as to be formed by a similar process. The material of the dielectric layer TM may be silicon nitride, silicon oxide, or other materials. For example, the refractive index of the lens layer LE may be 1.5, and the refractive index of the dielectric layer TM may be not less than 1.7 and not more than 1.9.

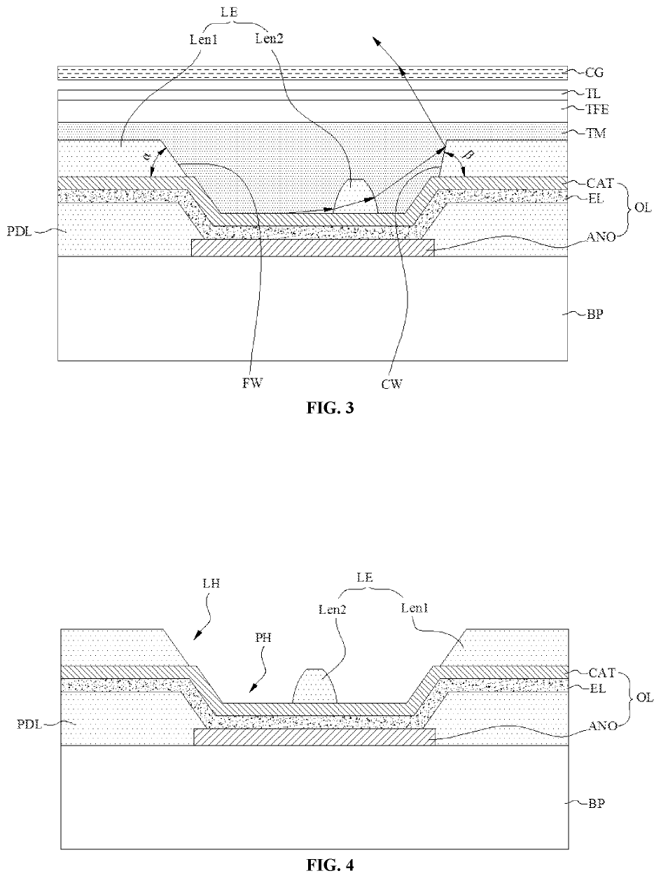

In some embodiments of the present disclosure, as shown in FIGS. 1 and 3, the lens layer LE may be located on a surface of the second electrode CAT away from the driving backplane BP. An orthogonal projection of the separating lens Len1 on the driving backplane BP is located within a range covered by the pixel definition layer PDL, and the intermediate lens Len2 may be located in the opening PH. That is, the separating lens Len1 corresponds to an area other than the light-emitting device OL, and the intermediate lens Len2 corresponds to the light-emitting device OL. At the same time, since the second electrode CAT may recess at the opening PH, causing that at least a portion of the intermediate lens Len2 may be located at a side of the separating lens Len1 close to the driving backplane BP. The dielectric layer TM covers the lens layer LE and the second electrode CAT that is not covered by the lens layer LE. A surface of the lens dielectric layer away from the driving backplane BP may be planar. In addition, the encapsulation layer TFE may cover the dielectric layer TM.

In some embodiments of the present disclosure, as shown in FIG. 2, the lens layer LE may cover the touch layer TL, i.e., the lens layer LE may cover the electrode layer of the touch layer TL, and at the same time, the dielectric layer TM may be utilized in place of the planarization layer covering the touch layer TL in order to simplify the structure. The polarizing layer may cover the dielectric layer TM, and the transparent cover plate CG may be located at a side of the polarizing layer away from the driving backplane BP.

In some embodiments of the present disclosure, the lens layer LE may be located on the surface of the second electrode CAT away from the driving backplane BP, the first inorganic layer of the encapsulation layer TFE may be used as the dielectric layer TM, and a thickness of the first inorganic layer may be made not less than 2 μm.

Furthermore, in other embodiments of the present disclosure, the lens layer LE may also be located on the surface of the encapsulation layer TFE away from the driving backplane BP, and the touch layer TL is located on a side of the dielectric layer TM away from the driving backplane BP. The location of the lens layer LE is not specifically limited herein.

The specific structures of the light-transmitting hole LH and the intermediate lens Len2 are exemplarily illustrated in detail below.

As shown in FIGS. 1-3, a portion of the light emitted by the light-emitting device OL within the range covered by the intermediate lens Len2 may be emitted out from the outer peripheral surface of the intermediate lens Len2 and undergo a refraction at the interface between the outer peripheral surface and the dielectric layer TM, and the refracted light converges in the direction perpendicular to the driving backplane BP so as to facilitate total reflection at the sidewall of the light-transmitting hole LH. At the same time, a portion of the light emitted by the light-emitting device OL corresponding to one light-transmitting hole LH may pass through the outer peripheral surface of the intermediate lens Len2 and undergo two refractions in the process of passing through, and the two refractions may cause the light to converge in the direction perpendicular to the driving backplane BP, which may likewise increase the quantity of light that undergoes total reflection at the sidewall of the light-transmitting hole LH, which is finally beneficial for improving the light output efficiency.

In some embodiments of the present disclosure, in one opening PH and the intermediate lens Len2 in the light-transmitting hole LH corresponding to the opening PH, an orthogonal projection of the intermediate lens Len2 on the driving backplane BP covers a center of an orthogonal projection of the opening PH on the driving backplane BP, i.e., the intermediate lens Len2 covers the center of the light-emitting range of the light-emitting device OL. At the same time, the center of the orthogonal projection of the light-transmitting hole LH on the driving backplane BP may coincide with the center of the orthogonal projection of the corresponding openings PH on the driving backplane BP, and the shape of the light-transmitting hole LH may be the same as that of its corresponding opening PH, that is, the shape of the light-transmitting hole LH may be the same as that of its corresponding light-emitting device OL.

The following is an exemplary illustration by taking an example of the intermediate lens Len2 covering the center of the light-emitting range of the light-emitting device OL.

As shown in FIGS. 6-10, the light-transmitting hole LH may be surrounded by a plurality of sidewalls, and the sidewalls may be planar surfaces or curved surfaces. The outer peripheral surface of the intermediate lens Len2 may be surrounded by a plurality of side surfaces, and the side surfaces include at least one lens side surface parallel to an orthogonal projection, on the driving backplane BP, of at least one of the sidewalls of the light-transmitting hole LH where the intermediate lens is located, i.e., at least a portion of a contour of the orthogonal projection of one of the sidewalls on the driving backplane BP is parallel to at least a portion of a contour of the orthogonal projection of one of the lens side surfaces on the driving backplane BP. A lens side surface and sidewall that have such a parallel relationship may be defined herein as the parallel lens side surface and sidewall. Light emitted out from the lens side surface of the intermediate lens Len2 may irradiate on the parallel sidewall.

In some embodiments of the present disclosure, the outer peripheral surface of the intermediate lens Len2 may have the same shape on the driving backplane BP as the light-transmitting hole LH where the intermediate lens Len2 is located. For example, the orthographic projection of the intermediate lens Len2 on the driving backplane BP and the orthographic projection of the light-transmitting hole LH on the driving backplane BP may both be polygons, and the lens side surfaces of the intermediate lens Len2 are provided in a one-to-one correspondence with the sidewalls of the light-transmitting hole LH.

In some embodiments of the present disclosure, as shown in FIG. 6, the width of the light-transmitting hole LH in the row direction X is less than the length of the light-transmitting hole LH in the column direction Y Corresponding to the shape of the light-transmitting hole LH, the width of the intermediate lens Len2, in the light-transmitting hole LH, in the row direction X is less than the length of the intermediate lens Len2 in the column direction Y The width of the light-transmitting hole LH in the row direction X is the distance between its two points, that are furthest away from each other in the row direction X, in the row direction X, i.e., the maximum width in the row direction X. The length of the light-transmitting hole LH in the column direction Y is the distance between its two points, that are furthest away from each other in the column direction Y, in the column direction Y, i.e., the maximum length in the column direction Y.

The width of the intermediate lens Len2 in the row direction X is the distance between the two points on its outer peripheral surface, that are furthest away from each other in the row direction X, in the row direction X, i.e., the maximum width in the row direction X. The length of the intermediate lens Len2 in the column direction Y is the distance between the two points on its outer peripheral surface, that are furthest away from each other in the column direction Y, in the column direction Y, i.e., the maximum length in the column direction Y.

Furthermore, as shown in FIG. 6, the intermediate lens Len2 may be a strip-shape structure extending along the column direction Y In order to minimize the obstruction of the light, emitted from the light-emitting device OL, by the intermediate lens Len2 itself while serving to increase the total reflection of the sidewall of the light-transmitting hole LH, the sizes of the light-transmitting hole and the intermediate lens Len2 may be limited to a certain extent.

For example, in the row direction X, the ratio of the width b1 of the intermediate lens Len2 to the width b2 of the light-transmitting hole LH where the intermediate lens Len2 is located is not less than 10% and not more than 50%. Furthermore, b1/b2 is not less than 15% and not more than 20%.

In the column direction Y, the ratio of the length a1 of the intermediate lens Len2 to the length a2 of the light-transmitting hole LH where the intermediate lens Len2 is located is not less than 30% and not greater than 80%. Furthermore, a1/a2 is not less than 50% and not more than 60%.

As shown in FIG. 6, in order to increase the area of the outer peripheral surface of the intermediate lens Len2 to facilitate light output, two lens side surfaces of the intermediate lens Len2 may both have a plurality of recessed portions GR spaced apart, so as to make the outer peripheral surface of the intermediate lens Len2 uneven. The depths of the recessed portions GR may be the same. Based on the recessed portions GR, the size of the intermediate lens Len2 may be further limited as follows.

In the row direction, the ratio of the depth b3 of the recessed portion GR to the width b1 of the intermediate lens Len2 is not less than 10% and not more than 40%. Furthermore, b3/b1 is not less than 20% and not more than 25%. The depth of the recessed portion GR may be the distance in the row direction X between a point, of the recessed portion GR, and a point, of the un-recessed area, that are farthest away from each other.

In the column direction Y, the ratio of the distance a3, between one end of the intermediate lens Len2 and the lowest point of a recessed portion GR closest to that end, to the length a1 of the intermediate lens Len2 is not less than 10% and not more than 50%. Furthermore, a3/a1 is not less than 25% and not more than 33%. The lowest point of the recessed portion GR is the point at which it has the largest depth, i.e., the point farthest away from the un-recessed area in the row direction X.

In some embodiments of the present disclosure, as shown in FIG. 6, the outer peripheral surface of the intermediate lens Len2 may be surrounded and smoothly connected by a plurality of curved lens side surfaces, such that the outer peripheral surface of the intermediate lens Len2 is free of tips. In addition, to ensure uniformity of light output from the intermediate lens Len2 to both sides, the orthographic projection of the intermediate lens Len2 on the driving backplane BP is an axisymmetric figure, and the axis of symmetry is a straight line along the column direction Y passing through the center of the orthographic projection of the light-transmitting hole LH on the driving backplane BP. The two lens side surfaces of the intermediate lens Len2 may be symmetric about this axis of symmetry. For example, one lens side surface of the intermediate lens Len2 has two recessed portions GR, which are provided symmetrically about the axis of symmetry.

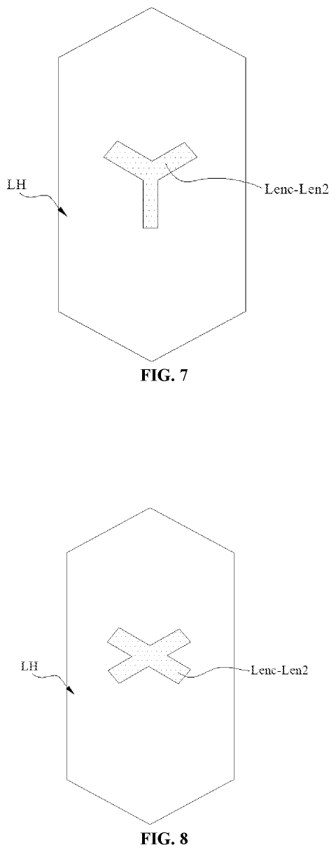

Of course, the intermediate lens Len2 may take other forms. For example, as shown in FIGS. 7 and 8, in some embodiments of the present disclosure, the intermediate lens Len2 may include a plurality of extension portions Lenc radially distributed. The number of the extension portions Lenc may be three, four, or more. The extension portions Lenc may converge in the same region, and an orthogonal projection of this region on the driving backplane BP covers the center of the orthogonal projection of the light-transmitting hole LH on the driving backplane BP. At the same time, at least one extension portion Lenc is parallel to an orthogonal projection, on the driving backplane BP, of a sidewall of the light-transmitting hole LH where the at least one extension portion Lenc is located, i.e., at least a portion of a contour of the orthogonal projection, on the driving backplane BP, of at least extension portion Lenc is parallel to at least a portion of a contour of the orthogonal projection, on the driving backplane BP, of one sidewall of the light-transmitting hole LH where the at least one extension portion Lenc is located, i.e., the extension direction of at least one extension portion Lenc is parallel to the extension direction of one sidewall of the light-transmitting hole LH where the at least one extension portion Lenc is located. For ease of description, an extension portion Lenc and a sidewall of a light-transmitting hole LH where the extension portion Lenc is located, orthogonal projections of which have such a parallel relationship, are defined herein as the extension portion Lenc being parallel to that sidewall. In order to facilitate the propagation of light transmitted through the outer peripheral surface of the intermediate lens Len2 towards the sidewall of the light-transmitting hole LH, each of the extension portions Lenc may be provided parallel to a sidewall of the light-transmitting hole LH where the extension portions are located. Of course, the number of the extension portions Lenc may be fewer than the number of the sidewalls of the light-transmitting hole LH where the extension portions Lenc are located.

The following is an exemplary illustration based on a hexagonal light-transmitting hole LH.

As shown in FIG. 6, in an embodiment of the present disclosure, the orthographic projection of the light-transmitting hole LH on the driving backplane BP is a hexagon, and the opening PH has the same shape as the light-transmitting hole LH. Accordingly, the sidewalls of the light-transmitting hole LH are six, i.e., the light-transmitting hole LH is surrounded by six planar sidewalls FW, where two planar sidewalls FW extend along the column direction Y, and at least a portion of contours of orthogonal projections of the two planar sidewalls FW on the driving backplane BP are provided parallel.

The intermediate lens Len2 may extend along a central axis passing through the center of the light-transmitting hole LH. The outer peripheral surface of the intermediate lens Len2 has four recessed portions GR. The four recessed portions GR are symmetrically distributed on both sides of the central axis. The outer peripheral surface of the intermediate lens Len2 is a smooth curved surface.

As shown in FIG. 7, in an embodiment of the present disclosure, the intermediate lens Len2 may include three extension portions Lenc, one extension portion Lenc is parallel to two planar sidewalls FW extending along the column direction Y, and two extension portions Lenc are provided parallel to the other two planar sidewalls FW, respectively. In other words, the three extension portions Lenc may form a “Y”-shape structure.

As shown in FIG. 8, in an embodiment of the present disclosure, the intermediate lens Len2 may include four extension portions Lenc, where two extension portions Lenc extend along the same direction and are parallel to one planar sidewall FW, and the other two extension portions Lenc extend along the same direction and are parallel to another planar sidewall FW, i.e., the four extension portions Lenc may form an “X”-shape structure.

After simulating the light output rate in the above embodiments of FIGS. 6-8, the light output rate of the prior art as well as the embodiments of FIGS. 6-8 may be obtained, and the simulation results are shown in the following table:

| solutions | light output rate |
|---|---|
| prior art | 10.20% |
| the embodiment of FIG. 6 | 11.75% |
| the embodiment of FIG. 7 | 12.38% |
| the embodiment of FIG. 8 | 12.01% |

It can be seen that after adopting the embodiments of FIGS. 6-8 of the present disclosure, the light output rate of the display panel is improved.

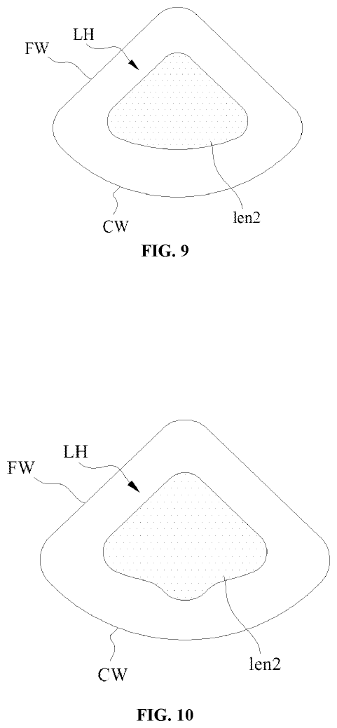

As shown in FIGS. 9 and 10, in some embodiments of the present disclosure, the sidewalls of the light-transmitting hole LH may include two planar sidewalls FW and one curved sidewall CW, the light-transmitting hole LH may be surrounded by the two planar sidewalls FW and the one curved sidewall CW, and the orthographic projection of the light-transmitting hole LH on the driving backplane BP may be fan-shaped. Accordingly, the outer peripheral surface of the intermediate lens Len2 may be surrounded by two planar side surfaces and one curved side surface, and the two planar side surfaces are parallel to the two planar sidewalls FW, respectively. As shown in FIG. 9, the curved side surface and the curved sidewall CW are cambered surfaces with the same curvature. Of course, as shown in FIG. 10, the curved side surface may also be a wavy curved surface, i.e., the curved side surface may have a protrusion protruding towards the curved sidewall CW, and, of course, a curved surface may be used.

In addition, as shown in FIG. 3, since the light-transmitting hole LH is a fan-shaped structure, when the light-transmitting hole LH is formed in the lens layer LE, the slope R of the curved sidewall CW is greater than the slope α of the planar sidewall FW, i.e., R is greater than a. As the intermediate lens Len2 may make the light emitted out from the curved side surface thereof more convergent, the light irradiated to the curved sidewall CW may be more prone to total reflection, which is favorable for reducing the total reflection at the transparent cover plate CG. Of course, it is also possible to form the lens layer LE by means of a half-tone mask and to make the slope of the curved sidewall CW greater than the slope of the planar sidewall FW.

The following is an exemplary illustration by taking the example of the intermediate lens Len2 not covering the center of the light-emitting range of the light-emitting device OL.

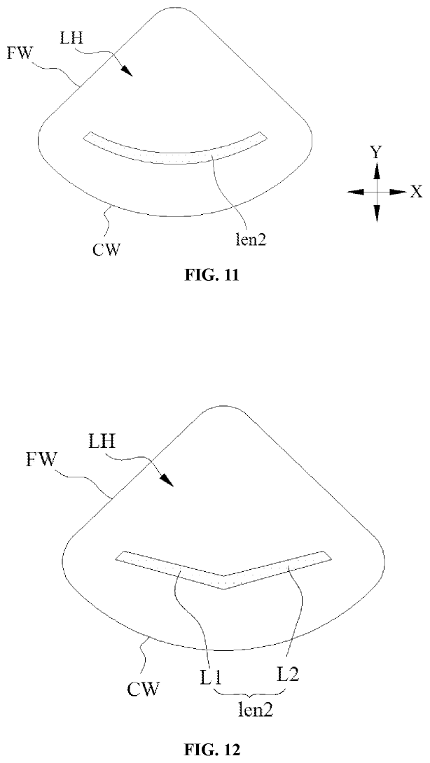

As shown in FIGS. 11-16, in some embodiments of the present disclosure, the sidewalls of the light-transmitting hole LH may include two planar sidewalls FW and one curved sidewall CW, the light-transmitting hole LH may be surrounded by the two planar sidewalls FW and the one curved sidewall CW, and the orthographic projection of the light-transmitting hole LH on the driving backplane BP may be fan-shaped. Accordingly, the outer peripheral surface of the intermediate lens Len2 may be surrounded by two planar side surfaces and one curved side surface, and the two planar side surfaces are parallel to the two planar sidewalls FW, respectively. In addition, since the light-transmitting hole LH is a fan-shaped structure, when the light-transmitting hole LH is formed in the lens layer LE, the slope β of the curved sidewall CW is greater than the slope α of the planar sidewall FW. As the intermediate lens Len2 may make the light emitted out from the curved side surface thereof more convergent, the light irradiated to the curved sidewall CW may be more prone to total reflection, which is favorable for reducing the total reflection at the transparent cover plate CG. Of course, it is also possible to form the lens layer LE by means of a half-tone mask and to make the slope of the curved sidewall CW greater than the slope of the planar sidewall FW.

The center of the light-emitting device OL corresponds to the center of the light-transmitting hole LH, and since the light emitted from the center of the light-emitting device OL and its surroundings does not undergo total reflection at the sidewall of the light-transmitting hole LH to a large extent, and, in particular, the problem of the light not undergoing total reflection at the curved sidewall CW is more obvious, in order to block the light as little as possible under the condition that total reflection of the light at the sidewall of the light-transmitting hole LH is increased, the intermediate lens Len2 may be made to be a strip-shape structure, and the intermediate lens Len2 is located between the curved sidewall CW and the center of the light-transmitting hole LH where the intermediate lens Len2 is located, so as to make use of the intermediate lens Len2 for refracting light to make the light emitted by the light-emitting device OL to be totally reflected at the curved sidewall CW. At the same time, the intermediate lens Len2 may minimize the obstruction of the light-emitting device OL, thereby maximizing the light output rate. It should be illustrated that the fact that the aforementioned intermediate lens Len2 can increase the total reflection at the curved sidewall CW does not mean that it can only increase the total reflection at the curved sidewall CW, but due to the presence of the intermediate lens Len2, for the light emitted by the light-emitting device OL that passes through the outer peripheral surface of the intermediate lens Len2, at least a portion of the light may be caused to undergo total reflection at the sidewall of the light-transmitting hole LH, so that the light output efficiency is improved on the whole. Of course, the curved side surface may also be a wavy curved surface or other curved surfaces, but the shape formed by it and the two planar side surfaces may still be regarded as fan-shaped.

As shown in FIG. 11, in some embodiments of the present disclosure, the strip-shape intermediate lens Len2 may be made to be a curved-strip-shape structure extending along a direction parallel to the curved sidewall CW of the light-transmitting hole LH where the intermediate lens is located so as to facilitate light irradiation from the curved-strip-shape structure to the curved sidewall CW. In addition, the curvature of the curved side surface of the intermediate lens Len2 and the curvature of the curved sidewall CW may be the same. The “parallel” mentioned in this article is not limited to non-intersection between two straight lines or planes, but also includes non-intersection between two cambered surfaces or other curved surfaces.

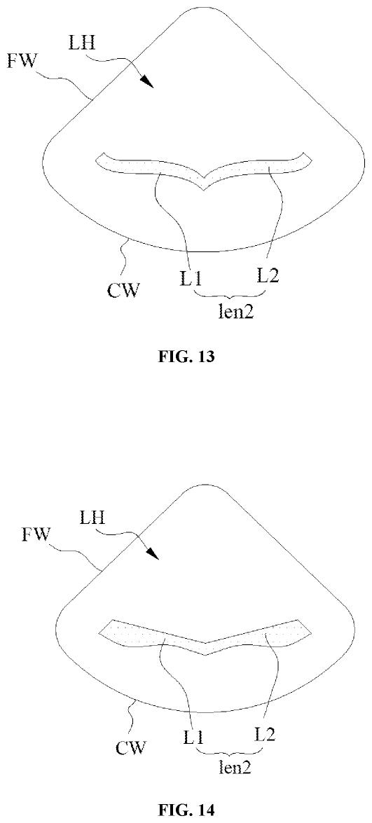

As shown in FIGS. 12-14, in some embodiments of the present disclosure, the strip-shape intermediate lens Len2 may include a first segment L1 and a second segment L2 connected at a specified angle, and the specified angle may be an obtuse angle, such that an extending trajectory of the intermediate lens Len2 and a trajectory of the curved sidewall CW are substantially the same. The first segment L1 and the second segment L2 are symmetrically arranged about a central axis passing through, in the column direction Y, the center of the light-transmitting hole LH. That is, the shape of the orthographic projection of the intermediate lens Len2 on the driving backplane BP is an axisymmetric figure. As shown in FIG. 12, side surfaces of the first segment L1 and the second segment L2 may be planar surfaces. As shown in FIG. 13, the side surfaces of the first segment L1 and the second segment L2 may be curved surfaces, such as wavy surfaces. As shown in FIG. 14, one side surface of the first segment L1 is a planar surface and the other side surface is a curved surface, and the distance between the two side surfaces of the first segment L1, i.e., the thickness of the first segment L1 decreases towards the second segment L2. The first segment L1 and the second segment L2 are symmetrically arranged, and the shapes of both are symmetrically arranged.

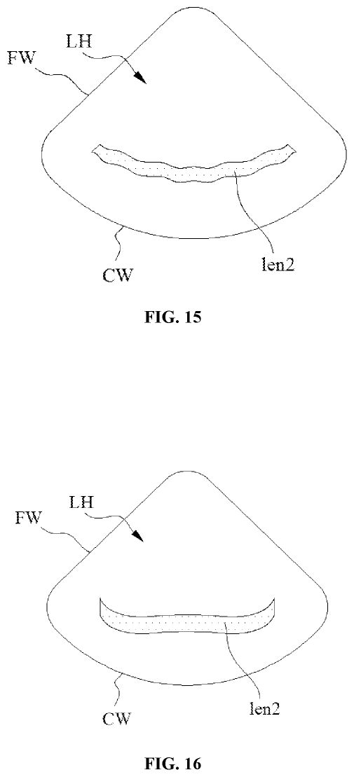

In some embodiments of the present disclosure, as shown in FIG. 15, the intermediate lens Len2 may extend along a curved trajectory, and its two side surfaces may be wavy surfaces. Additionally, as shown in FIG. 16, the intermediate lens may also extend along a straight line, and its two side surfaces may be curved surfaces. Of course, the two side surfaces of the intermediate lens may also be planar surfaces.

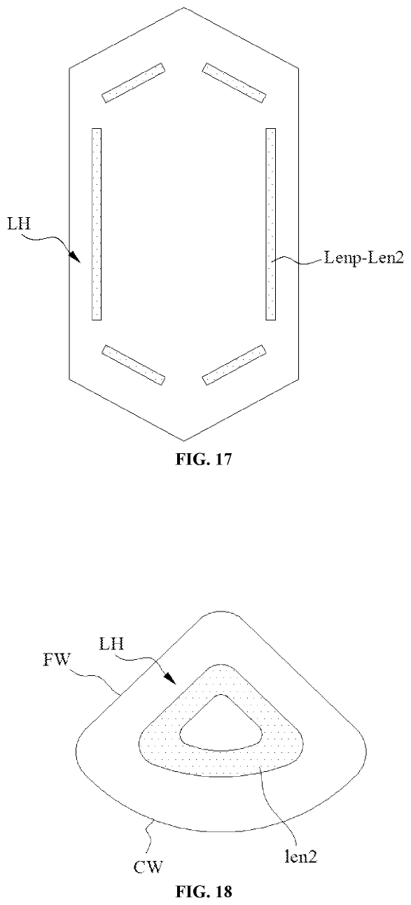

As shown in FIGS. 17-20, in some embodiments of the present disclosure, the orthographic projection of the light-transmitting hole LH on the driving backplane BP may be a polygon, fan, or other shape as described above. The intermediate lens Len2 may be of an annular shape and surrounds outside the center of the light-transmitting hole LH where the intermediate lens is located. The shape of the outer peripheral surface of the intermediate lens Len2 may be the same as the shape of the light-transmitting hole LH, e.g., as shown in FIG. 18, the outer peripheral surface of the intermediate lens Len2 and the light-transmitting hole LH are both fan-shaped, and the fan-shaped structure may be referred to the description above, and are not described in detail herein.

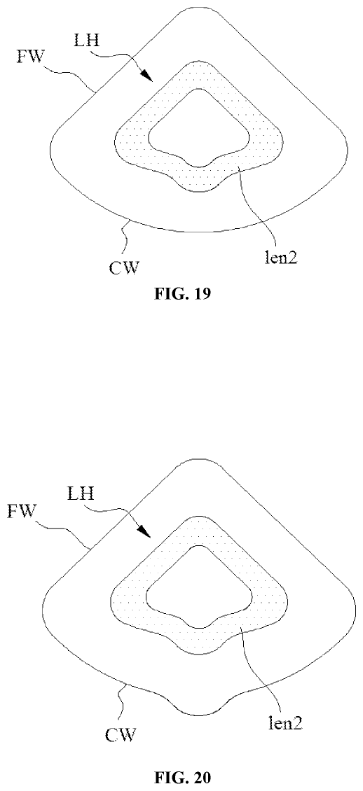

On the basis of FIG. 18, as shown in FIG. 19, when the intermediate lens Len2 is fan-shaped, its curved side surface may have a protrusion protruding outwards, or the curved side surface may be a wavy surface.

As shown in FIG. 20, in order to increase the area of the sidewall of the light-transmitting hole LH, on the basis of FIG. 19, a protrusion may be provided on a position of the curved sidewall CW, of the light-transmitting hole LH, corresponding to the protrusion of the curved side surface of the intermediate lens Len2, so that the shape of the light-transmitting hole LH is the same as the shape of the intermediate lens Len2.

The orthographic projection of the center of the intermediate lens Len2 on the driving backplane BP and the orthographic projection of the center of the light-emitting device OL on the driving backplane BP may coincide with the orthographic projection of the center of the light-transmitting hole LH on the driving backplane BP, so that light emitted from the center of the light-emitting device OL and its surroundings may be irradiated to the sidewall of the light-transmitting hole LH after passing through the intermediate lens Len2, and the ratio of total reflection may be increased, thereby increasing the overall light output efficiency.

As shown in FIGS. 19 and 20, the intermediate lens Len2 may be a continuous closed annulus. As shown in FIG. 18, the intermediate lens Len2 may include a plurality of lens units Lenp spaced apart around the center of the light-transmitting hole LH where the intermediate lens is located. The lens unit Lenp may be a strip-shape structure, the intermediate lens Len2 may be an interrupted annular structure, and the extension direction of at least a portion of the lens units Lenp may be parallel to a portion of the sidewalls of the light-transmitting hole LH. For example, both the intermediate lens Len2 and the light-transmitting hole LH are hexagons, and the intermediate lens Len2 includes six lens units Lenp, and each of the lens units is parallel to one sidewall of the light-transmitting hole LH.

It should be illustrated that the above description of the intermediate lens Len2 and the light-transmitting hole LH is based on an example of one light-transmitting hole LH and an intermediate lens Len2 located in the light-transmitting hole LH, and does not limit that all light-transmitting holes LH are provided with the intermediate lens Len2.

For example, as shown in FIG. 21, in some embodiments of the present disclosure, the area of the light-emitting device OL that emits blue light is larger than the area of the light-emitting device OL that emits red light and the area of the light-emitting device OL that emits green light, the intermediate lens Len2 of any of the above mentioned embodiments may be provided only in the light-transmitting hole LH corresponding to the light-emitting device OL that emits blue light, and the intermediate lens Len2 may not be provided in the light-transmitting hole LH corresponding to the light-emitting device OL that emits red light or the light-transmitting hole LH corresponding to the light-emitting device OL that emits green light. Of course, in other embodiments of the present disclosure, the intermediate lens Len2 may be provided in the light-transmitting hole LH corresponding to each light-emitting device OL.

The present disclosure provides a manufacturing method of a display panel, and this display panel may be a display panel of any of the above embodiments. The manufacturing method may include steps S110-S150.

At step S110, a driving backplane is formed.

At step S120, a pixel definition layer and a plurality of light-emitting devices are formed at a side of the driving backplane. The plurality of light-emitting devices are spaced apart at the side of the driving backplane, and the pixel definition layer is provided with a plurality of openings defining ranges of the light-emitting devices in one-to-one correspondence.

At step S130, a lens layer is formed at a side of the light-emitting device away from the driving backplane. The lens layer includes a separating lens and an intermediate lens. The separating lens is provided with a light-transmitting hole. The intermediate lens is located within a range surrounded by the light-transmitting hole and is spaced apart from a sidewall of the light-transmitting hole. In a direction perpendicular to the driving backplane, one opening is located opposite to one light-transmitting hole. The light-transmitting hole and the opening expand in a direction away from the driving backplane, and an outer peripheral surface of the intermediate lens contracts in the direction away from the driving backplane.

At step S140, a dielectric layer covering the lens layer and filling the light-transmitting hole is formed. The dielectric layer has a larger refractive index than the lens layer.

At step S150, a transparent cover plate is formed at a side of the dielectric layer away from the driving backplane.

In some embodiments of the present disclosure, as shown in FIGS. 2 and 22, at step S130, for the solution of a fan-shaped light-transmitting hole above, the slope β of the curved sidewall CW may be made the same as the slope α of the planar sidewall FW by using a half-tone mask HTM. Specifically, in forming the lens layer LE, a negative photoresist may be utilized to form the lens material layer LEL, and then the half-tone mask HTM may be utilized to expose and develop the lens material layer. The half-tone mask HTM has a light-transmitting area, a semi-light-transmitting area HTA, and a shading area TA. The shading area TA corresponds to an area in which the light-transmitting hole LH is to be formed, the light-transmitting area corresponds to an area (including the planar sidewall FW) in which the separating lens Len1 is to be formed, and the semi-light-transmitting area HTA corresponds to an area of the curved sidewall CW. Due to the presence of the semi-light-transmitting area HTA, the degree of corrosion of the developer solution at the curved sidewall CW may be enhanced, thereby reducing the slope β of the curved sidewall CW to be roughly equal, or, of course, the same as the slope α of the planar sidewall FW. For example, the slope β of the curved sidewall CW and the slope α of the planar sidewall FW may both be 59°. Of course, it is also possible to make the slope β of the curved sidewall CW consistent with the slope α of the planar sidewall in other ways. And the reduction of the slope β is favorable to increase the incident angle of the light, emitted from the light-emitting device OL, at the sidewall of the light-transmitting hole LH, facilitating the occurrence of total reflection.

It should be illustrated that FIG. 22 is only a schematic diagram illustrating the principle of the process, and does not constitute a limitation of the actual structure of the product in the process of performing step S130.

Details in the other steps of the above-described manufacturing method and the beneficial effects of the manufacturing method may be referred to the embodiments of the display panel above, and are not described in further detail herein.

It should be illustrated that although various steps of the manufacturing method in the present disclosure are depicted in the accompanying drawings in a particular order, it is not required or implied that the steps must be performed in that particular order or that all of the steps shown must be performed in order to achieve the desired results. Additionally or alternatively, certain steps may be omitted, multiple steps may be combined to be performed as a single step, and/or a single step may be broken down to be performed as multiple steps, etc.

The present disclosure also provides a display apparatus. The display apparatus may include a touch display panel of any of the above embodiments. The touch display panel is the display panel of any of the above-described embodiments, and the specific structure and beneficial effects thereof may be referred to the above-described embodiments of the display panel, and are not repeated herein. The display apparatus of the present disclosure may be an electronic device with a display function such as a cell phone, a tablet computer, and a television, and are not enumerated herein.

After considering the specification and practicing the present disclosure herein, those skilled in the art will easily come up with other embodiments of the present disclosure. The purpose of the present disclosure is to cover any variations, uses, or adaptations of the present disclosure, and these variations, uses, or adaptations follow the general principles of the present disclosure and include common knowledge or commonly used technical means in the technical field that are not disclosed in the present disclosure. The specification and embodiments are only considered exemplary, and the true scope and spirit of the present disclosure are indicated by the accompanying claims.

1. A display panel, comprising:
a driving backplane;
a plurality of light-emitting devices, spaced apart at a side of the driving backplane;
a pixel definition layer, located at a same side of the driving backplane as the light-emitting device, and provided with a plurality of openings, wherein the openings define ranges of the light-emitting devices in one-to-one correspondence;
a lens layer, located at a side of the light-emitting device away from the driving backplane, wherein the lens layer comprises a separating lens and an intermediate lens, the separating lens is provided with a light-transmitting hole, the intermediate lens is located within a range surrounded by the light-transmitting hole and is spaced apart from a sidewall of the light-transmitting hole; in a direction perpendicular to the driving backplane, one of the openings is located opposite to the light-transmitting hole; the light-transmitting hole and the opening expand in a direction away from the driving backplane, and an outer peripheral surface of the intermediate lens contracts in the direction away from the driving backplane;
a dielectric layer, covering the lens layer and filling the light-transmitting hole, wherein the dielectric layer has a larger refractive index than the lens layer; and
a cover plate, located at a side of the dielectric layer away from the driving backplane.

2. The display panel according to claim 1, wherein the light-emitting device comprises a first electrode, a light-emitting layer, and a second electrode sequentially stacked in the direction away from the driving backplane; wherein
first electrodes of the light-emitting devices are spaced apart, and are exposed by the openings in one-to-one correspondence; the light-emitting devices share the same second electrode; the second electrode covers on a side of the pixel definition layer away from the driving backplane and recesses into the opening; and the lens layer is located at a side of the second electrode away from the driving backplane; and
an orthogonal projection of the separating lens on the driving backplane is located within a range covered by the pixel definition layer, and the intermediate lens is located in the opening.

3. The display panel according to claim 1, further comprising:
an encapsulation layer, covering the light-emitting devices; and
a touch layer, located on a surface of the encapsulation layer away from the driving backplane; wherein the lens layer covers the touch layer; and the cover plate is located at a side of the touch layer away from the driving backplane.

4. The display panel according to claim 1, wherein in one of the openings and the intermediate lens in the light-transmitting hole corresponding to the one of the openings, an orthogonal projection of the intermediate lens on the driving backplane covers a center of an orthogonal projection of the opening on the driving backplane.

5. The display panel according to claim 1, wherein the light-transmitting hole is surrounded by a plurality of sidewalls; and the outer peripheral surface of the intermediate lens comprises at least one lens side surface parallel to an orthogonal projection, on the driving backplane, of at least one of the sidewalls of the light-transmitting hole where the intermediate lens is located.

6. The display panel according to claim 1, wherein a width of the light-transmitting hole in a row direction is less than a length of the light-transmitting hole in a column direction; and a width of the intermediate lens in the row direction is less than a length of the intermediate lens in the column direction.

7. The display panel according to claim 6, wherein the intermediate lens is a strip-shape structure extending along the column direction;
in the row direction, a ratio of the width of the intermediate lens to the width of the light-transmitting hole where the intermediate lens is located is not less than 10% and not more than 50%; and
in the column direction, a ratio of the length of the intermediate lens to the length of the light-transmitting hole where the intermediate lens is located is not less than 30% and not more than 80%.

8. The display panel according to claim 7, wherein two lens side surfaces of the intermediate lens both have a plurality of recessed portions spaced apart;
in the row direction, a ratio of a depth of the recessed portion to the width of the intermediate lens is not less than 20% and not more than 25%; and
in the column direction, a ratio of a distance, between one end of the intermediate lens and a lowest point of the recessed portion closest to the one end, to the length of the intermediate lens is not less than 10% and not more than 50%.

9. The display panel according to claim 7, wherein the outer peripheral surface of the intermediate lens is surrounded and smoothly connected by a plurality of curved lens side surfaces.

10. The display panel according to claim 5, wherein the intermediate lens comprises a plurality of extension portions radially distributed, and at least one of the extension portions is parallel to an orthogonal projection, on the driving backplane, of a sidewall of the light-transmitting hole where the intermediate lens is located.

11. The display panel according to claim 1, wherein the outer peripheral surface of the intermediate lens has a same shape on the driving backplane as the light-transmitting hole where the intermediate lens is located.

12. The display panel according to claim 1, wherein the light-transmitting hole is surrounded by two planar sidewalls and one curved sidewall; and the outer peripheral surface of the intermediate lens is surrounded by two planar side surfaces and one curved side surface; and
the two planar side surfaces are parallel to orthographic projections, on the driving backplane, of the two planar sidewalls respectively.

13. The display panel according to claim 1,
wherein the light-transmitting hole is surrounded by two planar sidewalls and one curved sidewall; and
the intermediate lens is a strip-shape structure, and is located between the curved sidewall and a center of the light-transmitting hole where the intermediate lens is located.

14. The display panel according to claim 13, wherein the intermediate lens comprises a first segment and a second segment connected at a specified angle, and the first segment and the second segment are symmetrically arranged about a central axis passing through, in a column direction, the center of the light-transmitting hole.

15. The display panel according to claim 13, wherein the intermediate lens is a curved-strip-shape structure extending along a direction parallel to the curved sidewall of the light-transmitting hole where the intermediate lens is located.

16. The display panel according to claim 1, wherein the intermediate lens is of an annular shape and surrounds outside a center of the light-transmitting hole where the intermediate lens is located.

17. The display panel according to claim 16, wherein the intermediate lens comprises a plurality of lens units spaced apart around the center of the light-transmitting hole where the intermediate lens is located.

18. The display panel according to claim 12, wherein the curved sidewall has a same slope as the planar sidewall.

19. A manufacturing method of a display panel, comprising:
forming a driving backplane;
forming a pixel definition layer and a plurality of light-emitting devices at a side of the driving backplane, wherein the plurality of light-emitting devices are spaced apart at the side of the driving backplane, and the pixel definition layer is provided with a plurality of openings defining ranges of the light-emitting devices in one-to-one correspondence;
forming a lens layer at a side of the light-emitting device away from the driving backplane, wherein the lens layer comprises a separating lens and an intermediate lens, the separating lens is provided with a light-transmitting hole, the intermediate lens is located within a range surrounded by the light-transmitting hole and is spaced apart from a sidewall of the light-transmitting hole; in a direction perpendicular to the driving backplane, one of the openings is located opposite to the light-transmitting hole; sizes of the light-transmitting hole and the opening expand in a direction away from the driving backplane, and an outer peripheral surface of the intermediate lens contracts in the direction away from the driving backplane;
forming a dielectric layer covering the lens layer and filling the light-transmitting hole, wherein the dielectric layer has a larger refractive index than the lens layer; and
forming a transparent cover plate at a side of the dielectric layer away from the driving backplane.

20. A display apparatus, comprising a display panel, wherein the display panel comprises:
a driving backplane;
a plurality of light-emitting devices, spaced apart at a side of the driving backplane;
a pixel definition layer, located at a same side of the driving backplane as the light-emitting device, and provided with a plurality of openings, wherein the openings define ranges of the light-emitting devices in one-to-one correspondence;
a lens layer, located at a side of the light-emitting device away from the driving backplane, wherein the lens layer comprises a separating lens and an intermediate lens, the separating lens is provided with a light-transmitting hole, the intermediate lens is located within a range surrounded by the light-transmitting hole and is spaced apart from a sidewall of the light-transmitting hole; in a direction perpendicular to the driving backplane, one of the openings is located opposite to the light-transmitting hole; the light-transmitting hole and the opening expand in a direction away from the driving backplane, and an outer peripheral surface of the intermediate lens contracts in the direction away from the driving backplane;
a dielectric layer, covering the lens layer and filling the light-transmitting hole, wherein the dielectric layer has a larger refractive index than the lens layer; and
a cover plate, located at a side of the dielectric layer away from the driving backplane.
